(19) United States
(12) Patent Application Publication
(10) Pub. No.: US 2018/0017696 A1
(43) Pub. Date: Jan. 18, 2018

(54) DETECTION SENSOR

(71) Applicants: KYUSHU INSTITUTE OF TECHNOLOGY, Fukuoka (JP); AI TECHNOLOGY, INC., Fukuoka (JP)

(72) Inventor: Yasushi Sato, Fukuoka (JP)

(21) Appl. No.: 15/716,125

(22) Filed: Sep. 26, 2017

Related U.S. Application Data
(63) Continuation-in-part of application No. PCT/JP2016/057661, filed on Mar. 10, 2016.

(30) Foreign Application Priority Data
Mar. 26, 2015 (JP) 2015-064418

(51) Int. Cl. G01V 3/08; G01R 23/12

(52) U.S. Cl. CPC G01V 3/088; G01R 23/12

(57) ABSTRACT

Provided is a detection circuit that has a first inductor connected to two opened input ends and detects an external signal having a waveform with a gradient at each input end. The detection sensor further includes an output circuit that has a second inductor magnetically coupled with the first inductor as a primary side. In the output circuit, a third inductor constituting a delay circuit having one end connected to an intermediate tap of the second inductor is connected. Diodes are respectively connected to terminals of the second inductor in a forward direction. Other terminals of the diodes are connected to another terminal of the third inductor via elements each having an impedance characteristic. The output circuit outputs a detection signal detected at the input ends, from the other terminal(s) of at least one of the diodes.

### CROSS REFERENCE TO RELATED APPLICATIONS

This application is a continuation-in-part of International Patent Application No. PCT/JP2016/057661, filed on Mar. 10, 2016, the disclosure of which including the specification, drawings and abstract is incorporated herein by reference in its entirety. International Patent Application No. PCT/JP2016/057661 is entitled to and claims the benefit of Japanese Patent Application No. 2015-064418, filed on Mar. 26, 2015, the disclosure of which including the specification, drawings and abstract is incorporated herein by reference in its entirety.

### BACKGROUND

### Technological Field

The present invention relates to a detection sensor using a detector circuit for detecting a frequency modulated signal.

### Description of Related Art

Several systems are generally known as a frequency modulation (hereinafter referred to as FM) detector circuit for detecting a frequency modulated signal. FIGS. 1A to 1C are diagrams showing FM detector circuits in the prior art. The FM detector circuits demodulate a signal modulated by converting frequency variations to voltage variations. FIG. 1A is a circuit diagram of the 2-tuning detector circuit, FIG. 1B is a circuit diagram of the Forster-Seeley detector circuit, and FIG. 1C is a circuit diagram of the ratio detector circuit. Each circuit has been known since a long time ago and has been commonly used in FM radio receivers and FM radios, for example.

Further, a detection device using the FM detector circuit as described above is disclosed in Japanese Unexamined Patent Publication No. 8-94762 (hereinafter referred to as Patent Document 1). The technique disclosed in Patent Document 1 includes: a human body detecting section that is attached to a glass portion such as a windowpane or a glass door and is made up of a transparent conductor 1; an oscillation circuit 8 that has a resonance circuit connected to the human body detecting section and changes its own oscillation frequency when a human body approaches the human body detecting section; an FM detector circuit 23 that detects a frequency signal outputted from the oscillation circuit 8; and a decision circuit 26 that decides whether or not the human body approaches based on a signal outputted from the FM detector circuit 23 and outputs a detection signal of the human body.

However, in the two-tuning detector circuit as shown in FIG. 1A, it is necessary to prepare two resonance circuits and arrange them properly, resulting in a complicated structure. Further, in the Forster-Seeley detector circuit and the ratio detector circuit as shown in FIGS. 1B and 1C, respectively, an input circuit on their primary side and an output circuit on their secondary side are electrically connected via a capacitor, so that an unnecessary high frequency noise generated on a rear stage side of the detector circuit is transmitted to a front stage side of the detector circuit, which degrades performance of the entire circuit.

Further, the technique disclosed in Patent Document 1 detects modulation of frequency due to the approach of a human body. However, the specific configuration and the like of the FM detector circuit are not disclosed, and the technique cannot solve the above problems.

### SUMMARY

The present invention provides a detection sensor that uses an unconventional FM detector circuit to detect modulation of frequency with high quality.

To achieve at least one of the above-mentioned objects, according to an aspect of the present invention, a detection sensor reflecting one aspect of the present invention includes a detection circuit that has a first inductor connected to two opened input ends and detects an external signal having a waveform with a gradient at each input end. The detection sensor further includes an output circuit that has a second inductor magnetically coupled with the first inductor as a primary side. In the output circuit, a third inductor constituting a delay circuit having one end connected to an intermediate tap of the second inductor is connected. Diodes are respectively connected to terminals of the second inductor in a forward direction. Other terminals of the diodes are connected to another terminal of the third inductor via elements each having an impedance characteristic. The output circuit outputs a detection signal detected at the input ends, from the other terminal(s) of at least one of the diodes.

As described above, the detection sensor reflecting one aspect of the present invention includes: a detection circuit that has a first inductor connected to two opened input ends and detects an external signal having a waveform with a gradient at each input end; and an output circuit that has a second inductor magnetically coupled with the first inductor as a primary side, wherein: a third inductor constituting a delay circuit having one end connected to an intermediate tap of the second inductor is connected; diodes are respectively connected to terminals of the second inductor in a forward direction; other terminals of the diodes are connected to another terminal of the third inductor via elements each having an impedance characteristic; and the output circuit outputs a detection signal detected at the input ends, from the other terminal(s) of at least one of the diodes. Therefore, it is not necessary to have such a configuration that determines a center frequency by a resonance circuit through a capacitor connecting the primary side and the secondary side as in the conventional FM detector circuit, so that the configuration can be simplified and an influence of unnecessary high frequency from the rear stage circuit can be prevented to perform detection with high quality.

In an example of the detection sensor reflecting one aspect of the present invention, each element having the impedance characteristic constitutes a parallel circuit of a capacitor and a resistor.

As described above, in the example of the detection sensor reflecting one aspect of the present invention, each element having the impedance characteristic constitutes the parallel circuit of the capacitor and the resistor, so that an integrating circuit is formed and it is possible to reliably detect a signal.

In an example of the detection sensor reflecting one aspect of the present invention, at least a capacitance component as a low-pass filter is connected between the terminals that output the detection signal.

As described above, in the example of the detection sensor reflecting one aspect of the present invention, at least the capacitance component as the low-pass filter is connected between the terminals that output the detection signal, so that it is possible to smooth the output signal and obtain a high-quality demodulated signal.

In an example of the detection sensor reflecting one aspect of the present invention, a ratio of the intermediate tap in the second inductor is determined in accordance with a distortion of the external signal detected by the detection circuit.

As described above, in the example of the detection sensor reflecting one aspect of the present invention, the ratio of the intermediate tap in the second inductor is determined in accordance with the distortion of the external signal detected by the detection circuit, so that an external signal in which actually a distortion often occurs is corrected and it is possible to perform a high-quality detection.

### BRIEF DESCRIPTION OF DRAWINGS

The advantages and features provided by one or more embodiments of the invention will become more fully understood from the detailed description given hereinbelow and the appended drawings which are given by way of illustration only, and thus are not intended as a definition of the limits of the present invention.

FIG. 1A to FIG. 1C are diagrams showing conventional FM detector circuits:

FIG. 2 is a functional block diagram of a detection sensor according to a first embodiment of the present invention:

FIG. 3 is a circuit diagram of the Forster-Seeley detector circuit;

FIG. 4 is a diagram showing a circuit configuration of the detection sensor according to the first embodiment;

FIG. 5A is a circuit diagram including the circuit configuration as shown in FIG. 4; and

FIG. 5B and FIG. 5C are signal waveform diagram of an input signal and a signal delayed by a third inductor.

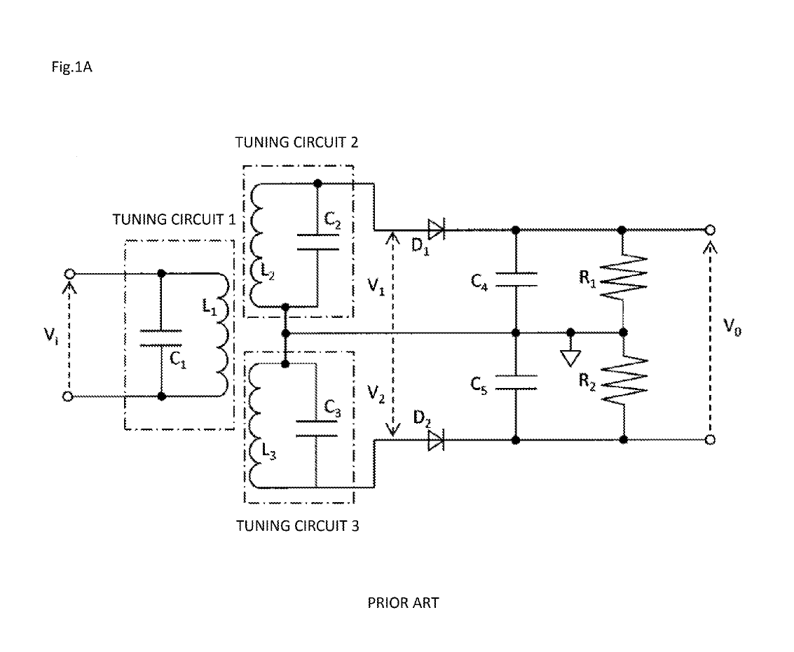

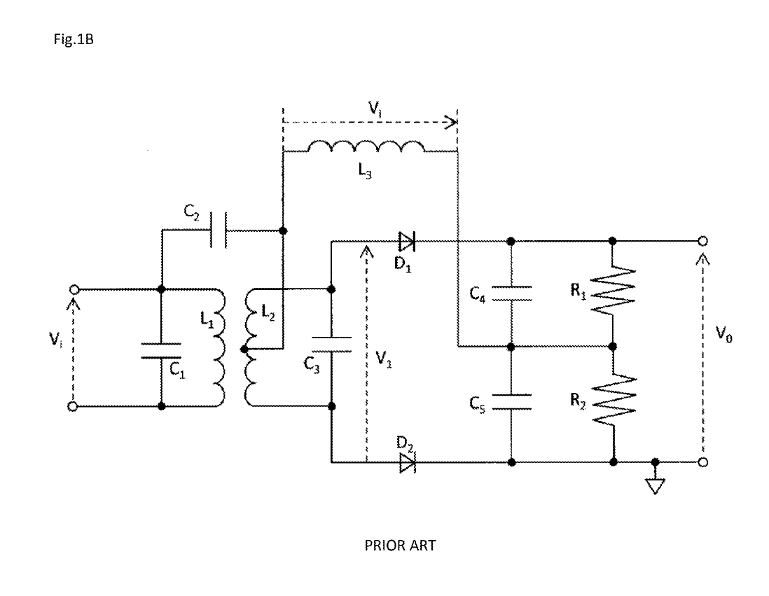

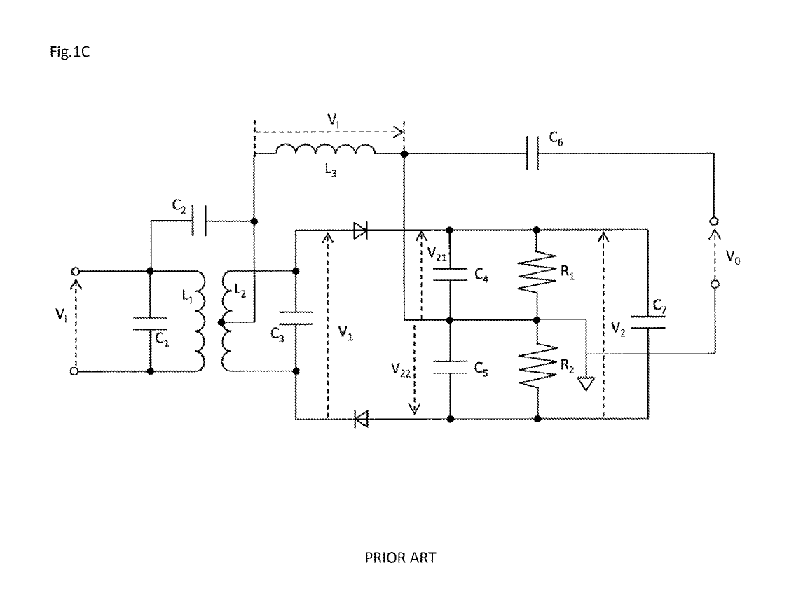

### DETAILED DESCRIPTION OF EMBODIMENTS

Hereinafter, one or more embodiments of the present invention will be described below with reference to the drawings. The same reference numerals are given to the same elements throughout the embodiments. However, the scope of the invention is not limited to the disclosed embodiments.

### First Embodiment

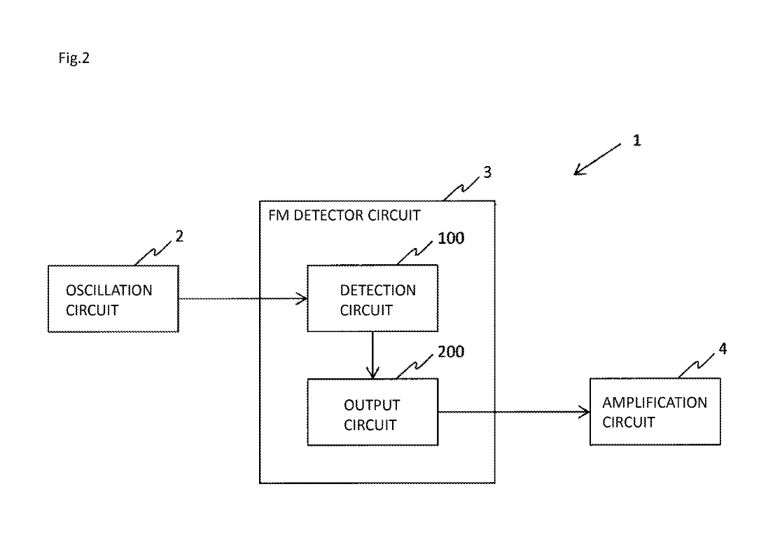

A detection sensor according to the Embodiment will be described with reference to FIG. 2 to FIG. 5C. The detection sensor according to the Embodiment is used as a human sensor that detects the presence or absence of a person, for example, and detects an object to be detected by detecting a frequency modulation of an oscillated signal. In other words, it is not intended to demodulate the signal by detecting an FM signal at a specific frequency, but it is intended to detect that frequency has been modulated. For this reason, in the Embodiment, a new technique that has not been used in the prior art, particularly in the configuration of an FM detector circuit, is used.

FIG. 2 is a functional block diagram of a detection sensor according to the Embodiment. A detection sensor 1 according to the Embodiment includes an oscillation circuit 2 that oscillates a signal of a predetermined frequency, an FM detector circuit 3 that detects an FM signal modulated by the object to be detected, an amplification circuit 4 that amplifies the detected signal. Further, the FM detector circuit 3 includes a detection circuit 100 that detects the FM signal and an output circuit 200 that outputs a demodulated signal of the detected signal. A signal oscillated by the oscillation circuit 2 has a gradient that can allow detection of a change in a differential value, which is assumed to be a sine wave, for example. The signal oscillated from the oscillation circuit 2 is detected by the detection circuit 100, and the modulation of frequency depending on the presence or absence of the object to be detected is outputted from the output circuit 200, thereby enabling detection of the presence or absence of the object to be detected.

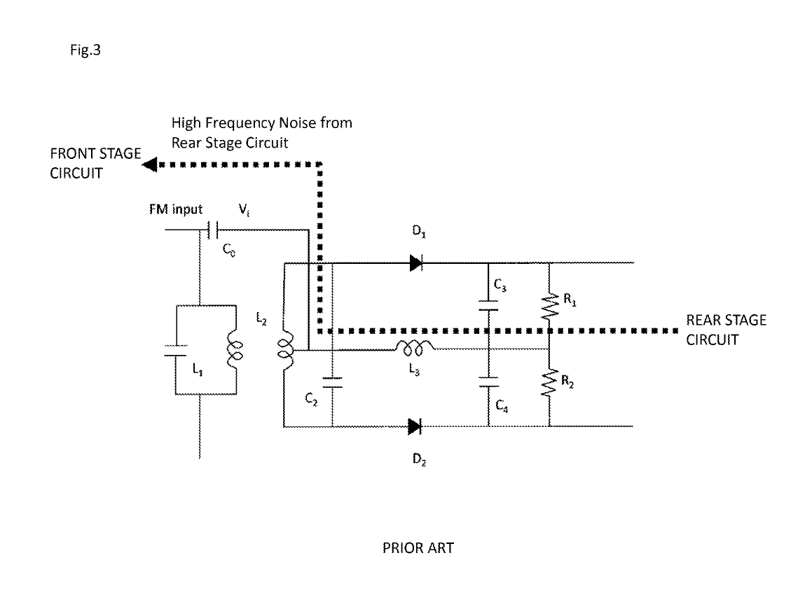

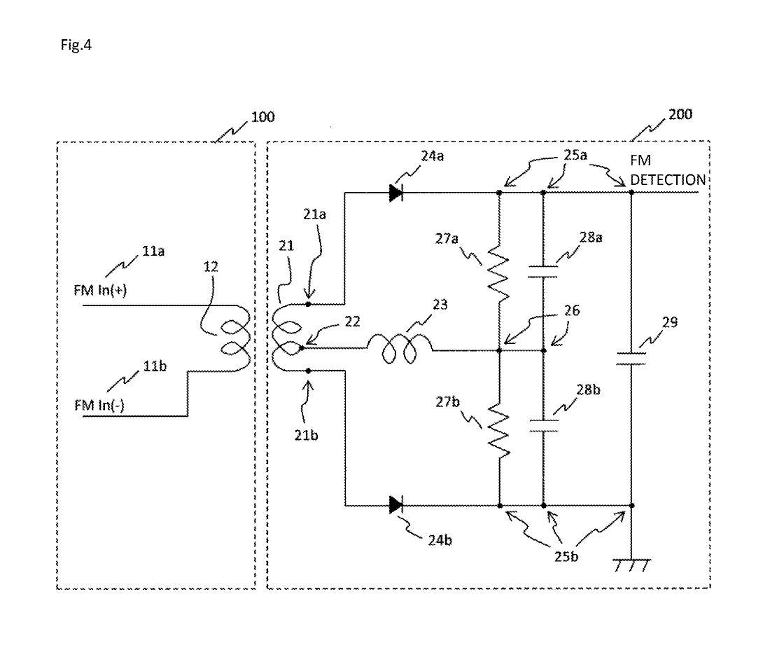

As an FM detector circuit, the circuits as described above have been known in the past, and one example thereof is shown in FIG. 3. FIG. 3 is a circuit diagram of the Forster-Seeley FM detector circuit. The principle of this system is to perform detecting based on the differences of two kinds of characteristics, inductive and capacitive, centering around a resonance frequency. In the circuit diagram of FIG. 3, a capacitor C₂ and an inductor L₂ form a resonance circuit, and a center frequency is obtained through a capacitor C₀. However, in such a method, since an inductor L₃ has a large value, it occurs a phenomenon that a high frequency goes through, and a circuit on a front stage side is susceptible to an unnecessary high frequency influence from a circuit on a rear stage side. Therefore, in the Embodiment, it is devised the circuit configuration as shown in FIG. 4, which eliminates the influence of the unnecessary high frequency from the circuit on the rear stage side, and detects the presence or absence of an object to be detected with high sensitivity.

FIG. 4 is a diagram showing a circuit configuration of the detection sensor according to the Embodiment. In FIG. 4, the detection sensor 1 is provided with a detection circuit 100 that has a first inductor 12 connected to two opened input ends 11a and 11b and detects, at each input end 11a, 11b, an external signal having a waveform with a gradient, oscillated from the oscillation circuit 2.

The detection sensor 1 is further provided with an output circuit 200 that has a second inductor 21 magnetically coupled with the first inductor 12 as a primary side. In the output circuit 200, a third inductor 23 constituting a delay circuit having one end connected to an intermediate tap 22 of the second inductor 21 is connected. Diodes 24a and 24b are respectively connected to terminals 21a and 21b of the second inductor 21 in a forward direction. Other terminals 25a and 25b of the diodes 24a and 24b are connected to another terminal 26 of the third inductor 23 via elements 27a, 27b, 28a, and 28b each having an impedance characteristic. The output circuit 200 outputs, from the other terminal 25a of the diode 24a, a detection signal detected at the input ends 11a and 11b (in the example of FIG. 4, the other terminal 25b of the diode 24b is grounded). In addition, a capacitance component 29 as a low-pass filter is connected between the terminals 25a and 25b that output the detection signal, as shown in FIG. 4. The circuit for the low-pass filter is not limited to this example. Any circuit including a capacitance component (for example, a circuit including a resistance component and a capacitance component) may be used as the low-pass filter.

As is apparent from the circuit diagram as shown in FIG. 4, the detection sensor 1 according to the Embodiment has only a magnetic coupling between the detection circuit 100 and the output circuit 200, and does not have any electrical connections as shown in FIG. 3. That is, it is possible to eliminate the influence of the unnecessary high frequency from the circuit on the rear stage side. The conventional FM detector circuit as shown in FIG. 3 is aimed at detecting a signal of a specific frequency with high quality. In contrast, the detection sensor 1 according to the Embodiment only have to detect the presence or absence of an object to be detected, that is, the change in frequency. Therefore, it is not necessary to construct a resonance circuit by making a wide range of frequency bands an object to be detected, so that it is possible to simplify the structure and improve the quality.

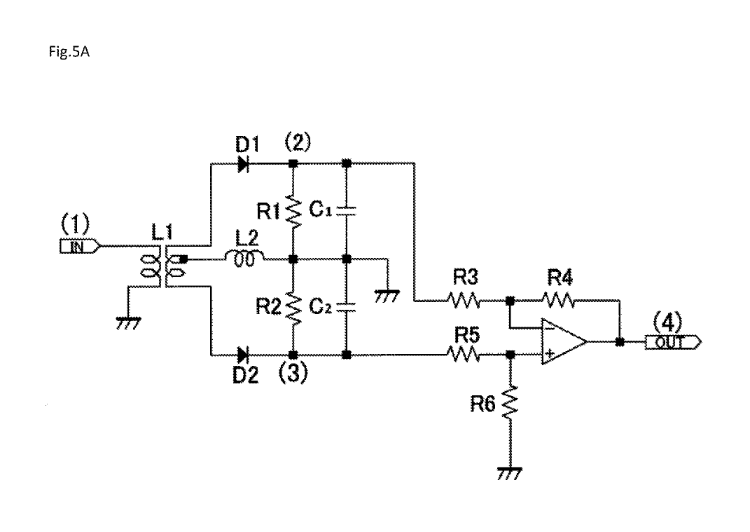

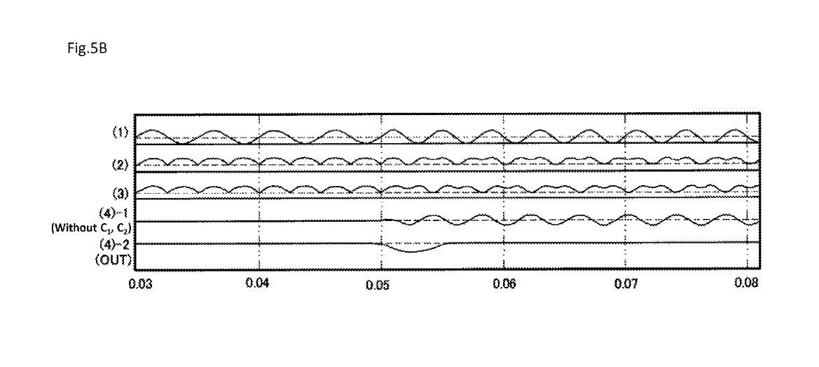

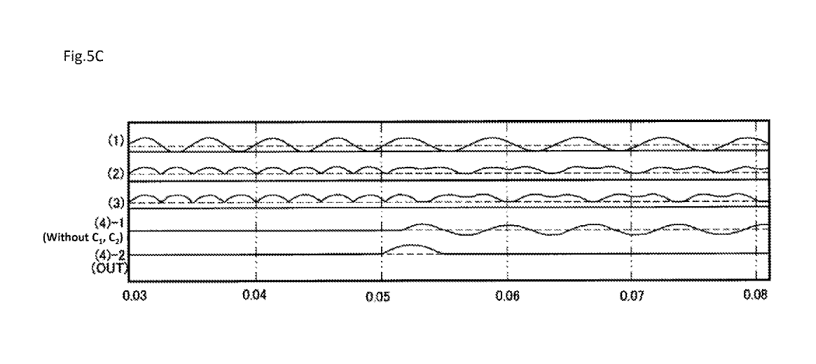

A specific detection method of the FM signal will be described. The detection sensor 1 according to the Embodiment is significantly different in principle from the conventional FM detector circuits and uses the third inductor 23 as a delay circuit. FIG. 5A is a circuit diagram including the circuit configuration as shown in FIG. 4. FIG. 5B and FIG. 5C are diagrams showing waveforms of input signals (1), detection signals (2), detection signals (3), output waveforms (4)-1 and (4)-2, respectively, in the circuit diagram of FIG. 5A. FIG. 5B shows an example of the waveforms in the case where a phase of the signal changes in a direction in which the phase is advanced, and FIG. 5C shows an example of waveforms in the case where the phase of the signal changes in a direction in which the phase is delayed. In FIG. 5B and FIG. 5C, a portion indicated by a dotted line shows a portion where the frequency changes and the phase changes. In addition, the output waveforms (4)-1 indicate output waveforms in the case where the capacitors C₁ and C₂ are not included, and the output waveforms (4)-2 show an example of the output waveform in the case of integration by the capacitors C₁ and C₂.

As can be seen from FIG. 5B and FIG. 5C, the output waveform changes toward a minus side when the phase is advanced, and the output waveform changes toward a plus side when the phase is delayed. By integrating the detected phase change, it is possible to output a voltage corresponding to the frequency deviation.

It should be noted that a ratio of the intermediate tap 22 of the second inductor 21 can be adjusted in accordance with a distortion of the input signal from the outside detected by the detection circuit 100. That is, even when a distortion occurs in the sine wave oscillated from the oscillation circuit 2, for example, a clean sine wave without distortion can be used as an input signal by adjusting the ratio of the intermediate tap 22 (i.e., by causing a distortion opposite to the above distortion) and a high quality sensor can be realized.

Although embodiments of the present invention have been described and illustrated in detail, it is clearly understood that the same is by way of illustration and example only and not limitation, the scope of the present invention should not be interpreted by terms of the appended claims.

What is claimed is:

1. A detection sensor comprising:
a detection circuit that has a first inductor connected to two opened input ends and detects an external signal having a waveform with a gradient at each input end; and
an output circuit that has a second inductor magnetically coupled with the first inductor as a primary side, wherein
a third inductor constituting a delay circuit having one end connected to an intermediate tap of the second inductor is connected,
diodes are respectively connected to terminals of the second inductor in a forward direction,
other terminals of the diodes are connected to another terminal of the third inductor via elements each having an impedance characteristic, and
the output circuit outputs a detection signal detected at the input ends, from the other terminal(s) of at least one of the diodes.

2. The detection sensor according to claim 1, wherein each element having the impedance characteristic constitutes a parallel circuit of a capacitor and a resistor.

3. The detection sensor according to claim 1, wherein at least a capacitance component as a low-pass filter is connected between the terminals that output the detection signal.

4. The detection sensor according to claim 1, wherein a ratio of the intermediate tap in the second inductor is determined in accordance with a distortion of the external signal detected by the detection circuit.
